(19) United States
(12) Patent Application Publication
(10) Pub. No.: US 2008/0304338 A1
(43) Pub. Date: Dec. 11, 2008

(54) SEMICONDUCTOR MEMORY DEVICE

(75) Inventor: Akihiko HARADA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/193,333

(22) Filed: Aug. 18, 2008

Related U.S. Application Data
(63) Continuation of application No. PCT/JP2006/304075, filed on Mar. 3, 2006.

(51) Int. Cl. G11C 7/00; G11C 8/00; G11C 5/14

(52) U.S. Cl. 365/189.011; 365/226; 365/230.03

(57) ABSTRACT

To provide a semiconductor memory device capable of increasing its drive capability at operating time while reducing a leak current at standby time without the s need to make a significant change to the design of an existing semiconductor memory device a semiconductor memory device having a memory cell comprises: a latch section that includes a transistor having a back gate to which a back gate voltage is supplied; a memory cell that includes a transfer gate constituting the memory cell the transfer gate being subjected to switching control by a word line signal and having a lo back gate to which a back gate voltage is supplied; and a back gate voltage control circuit that controls the back gate voltage based on an address signal.

### TECHNICAL FIELD

The present invention relates to a semiconductor memory device that performs a memory access operation by using word (row) lines and bit (column) lines.

### BACKGROUND ART

FIG. 7 is a block diagram showing a configuration of a RAM macro of a semiconductor memory device by taking “2 kw 1RW RAM (8 col/1 bit system)” as an example. As shown in FIG. 7, the RAM macro is divided into memory cell array sections 1 and 2, a word line (WL) driver/row decoder section 3, a column decoder/sense amplifier (sense amp)/write buffer sections 4 and 5, and a clock control/predecoder section 6, which are connected to an input/output buffer section 7.

FIG. 8 is a circuit diagram for explaining a drive line (word line) that drives a memory cell. One memory cell 10 includes two transfer gates 11 and 12 which are data input/output control transistors for controlling input/output of data on its input and output sides and a latch section 14 provided between the two transfer gates 11 and 12. Gates 11a and 12a of the transfer gates 11 and 12 are connected to a word line WL, and back gates 11b and 12b thereof are connected to a power source VSS. Further, output terminals of the transfer gates 11 and 12 are connected to bit lines (BL, BLX).

Operation of activating an arbitrary word line WL signal using an 8-bit address signal will be described with reference to FIG. 8.

In the case of 2 kw 1RW RAM (8 col/1 bit system), an 11-bit address signal is required in order to identify a memory cell. 8 bits of 11 bit-address signal from the input buffer is fully decoded using a predecoder 21, a row decoder 22 is then used to generate a row decode signal (1/256 hot) from the resultant signals, and a WL of a memory cell selected by the row decode signal is activated through a WL driver 23.

From the other 3-bit address signal, 1/8 hot column signal is generated using the column decoder sections 4 and 5 and is used for selection of data transmitted from an activated memory cell through the two bit lines BL and BLX. The selected data signal is then transmitted to the sense amplifier where the amplitude of the signal is amplified, and the resultant signal is transmitted to the output buffer (input/output buffer section 7) as valid data.

In conventional arts, irrespective of selection/nonselection of a memory cell, the back gate (hereinafter, referred to as “BG”) terminal of a transistor in a memory cell is connected to a VSS power supply in the case of an NMOS transistor, and is connected to a VDD power supply in the case of a PMOS transistor. The potentials of both the VDD and VSS power supplies are unique, so that the threshold voltage of a transistor dose not change basically unless the influence of a power supply noise is not taken into consideration.

Therefore, characteristics of a transistor constituting a selected memory cell and characteristics of a transistor in a nonselected memory cell are almost equal to each other, and both the transistors have a high threshold voltage for reducing standby power consumption. Therefore, the drive capability of an NMOS required at the data read time is low, Further, in an RAM including a large number of row lines like a large capacity memory, the load capacitance of the bit lines (BL, BLX) to be driven for the internal NMOS is large, so that there is a possibility that access time for the RAM may become longer to degrade system performance.

The capacity of a cache memory mounted on a high-performance processor increases as the generation progresses, and the power consumption of the cache memory occupies the majority of the power consumption (especially standby power consumption) in a chip. Thus, as a transistor to be used in a memory cell, one having a higher threshold voltage and a smaller leak current than a commonly-used transistor so as to achieve low power consumption.

A large capacity memory includes a large number of row lines because of its macro configuration and, accordingly, the length of the bit line (data) is increased, so that the load capacitance of the bit lines to be driven in a memory cell becomes large. Since the drive capability of the transistor in a memory cell is lower than that of a commonly-used transistor as described above, the time required for generating a potential difference for allowing the sense amplifier to operate, that is, the time required for recognizing “High” or “Low” becomes longer with the result that the memory access time becomes longer, which may restrict the chip performance.

Thus, in order to achieve both high-speed operation and low power consumption, it is necessary to dynamically carry out the algorithm of reducing the threshold value of the transistor at operating time so as to increase the drive capability of the transistor while increasing the threshold voltage of the transistor at standby time so as to reduce a leak current.

In view of the above, there is proposed a semiconductor integrated circuit having a configuration in which the threshold voltage of a field effect transistor is made variable. That is, at operating time, the threshold voltage of the transistor is reduced to increase the speed of data read/write operation for a storage holding node. Meanwhile, at standby time, the threshold voltage of the transistor is increased to reduce a leak current so as not to destroy and erase the data of the storage holding node (refer to, e.g., Patent Document 1).

### Patent Document 1: Japanese Patent Application Laid-Open Publication No. 10-264946

### SUMMARY

However, when the above transistor configuration disclosed in Patent Document 1 is applied to a memory cell, the drive line of the memory cell is selected by the column line. Therefore, in an existing bit cell, Pwells and Nwells are separated in parallel rows. Thus, when a column selection signal is used, the separation direction of the Pwell and Nwell needs to be changed to the vertical (column) direction, so that the configuration of the bit cell needs to be modified. The existing bit cell is optimized with the operating speed and integration degree taken into consideration, so that the modification of the bit cell greatly influences its performance.

In general, the column selection signal is fully decoded directly without being pre-decoded, so that in order to flexibly perform the selection of a drive line, it is necessary to separate the Well in units of 1-bit cell column, resulting in an increase in the area of the macro configuration in the column direction.

The present invention has been made to solve the above problems, and an 5 object thereof is to provide a semiconductor memory device capable of increasing its drive capability at operating time while reducing a leak current at standby time without the need to make a significant change to the design of an existing semiconductor memory device.

According to an aspect of the present invention, there is provided a semiconductor memory device having a memory cell, comprising: a latch section that includes a transistor having a back gate to which a back gate voltage is supplied; a memory cell that includes a transfer gate constituting the memory cell, the transfer gate being subjected to switching control by a word line signal and having a back gate to which a back gate voltage is supplied; and a back gate voltage control circuit that controls the back gate voltage based on an address signal.

### BRIEF DESCRIPTION OF THE DRAWINGS

FIG. 1 is a circuit diagram showing a drive circuit of a semiconductor memory device in an embodiment of the present invention;

FIG. 2 is a circuit diagram showing a back gate (BG) voltage control circuit in the embodiment of the present invention;

FIG. 3 is a circuit diagram showing a memory cell in the embodiment of the present invention;

FIG. 4 is an explanatory view showing operation of the embodiment of the present invention;

FIG. 5 is a block diagram showing the semiconductor memory device in the embodiment of the present invention;

FIG. 6 is a view showing the effect of the present invention;

FIG. 7 is a block diagram showing a conventional semiconductor memory device; and

FIG. 8 is a block diagram showing a conventional low decoder.

### DETAILED DESCRIPTION OF THE EMBODIMENTS

An embodiment of the present invention will be described below by referring to the accompanying drawings.

In an embodiment of the present invention, a BG terminal of a transistor constituting a memory cell is disconnected from a VDD or VSS power supply so as to change the potential of the BG terminal depending on selection/nonselection of a memory cell. This configuration allows the threshold voltage of the transistor in a selected memory cell to be reduced to thereby increase drive capability while allowing the threshold voltage of the transistor in a nonselected memory cell to be increased to thereby suppress a leak current. The above configuration can be achieved without the need to make a significant change to the design of an existing semiconductor memory device.

In the memory cell array, wells of the same type are sequentially arranged in the row direction for convenience of layout. Therefore, when a signal for selecting a row is used as an EN signal to apply a voltage to the BG terminal, the potential can be made variable depending on selection/nonselection of a memory cell. The selection/nonselection of a memory cell is made in units of a block obtained by dividing a memory cell into a plurality of blocks in the row direction.

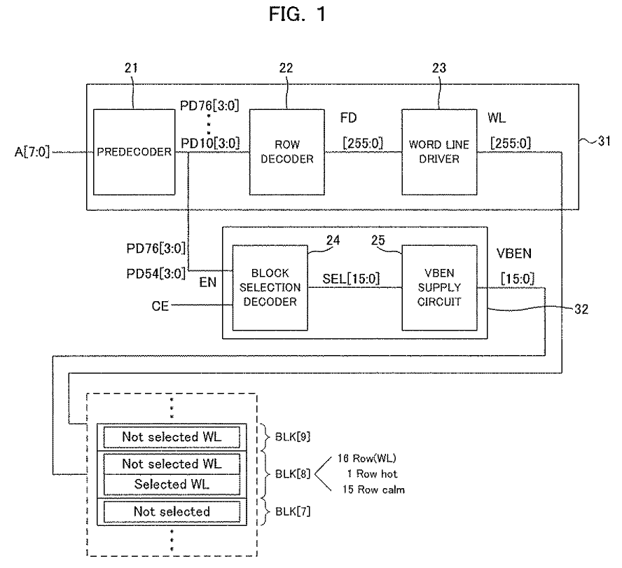

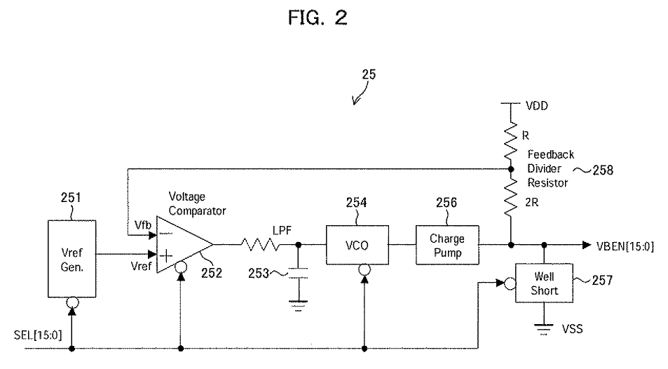

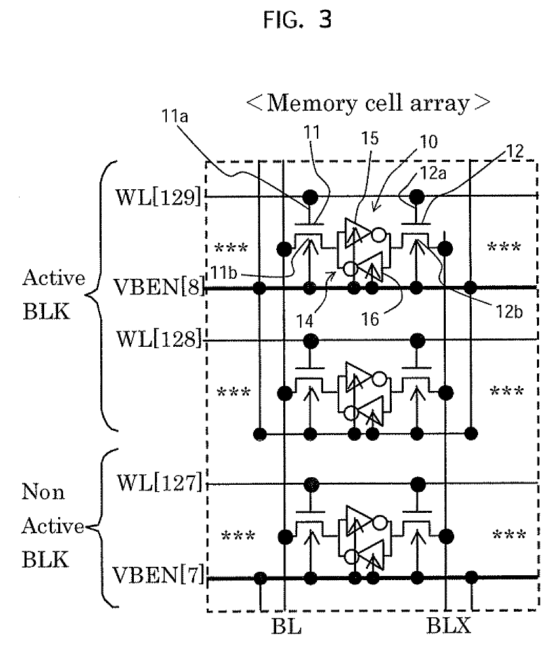

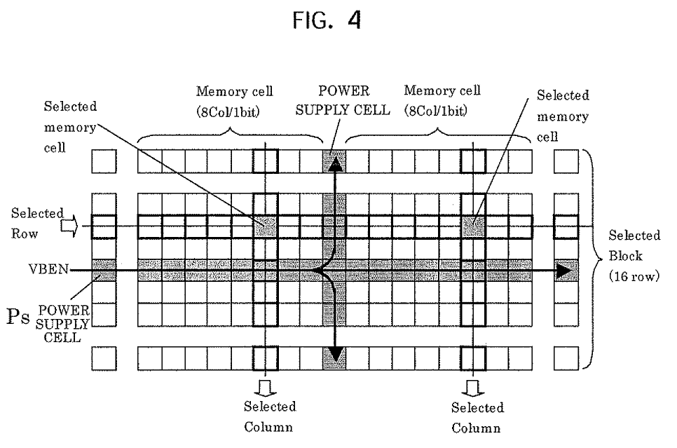

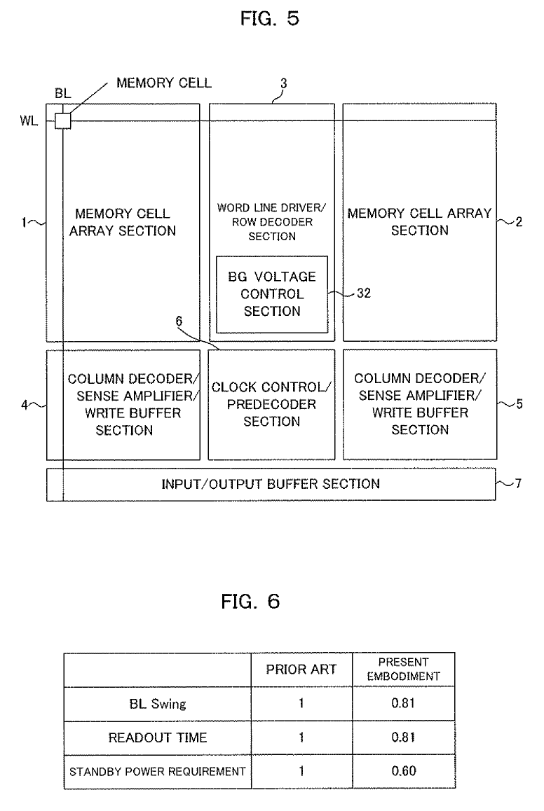

FIG. 1 is a circuit diagram showing a drive circuit of a semiconductor memory device in an embodiment of the present invention, FIG. 2 is a circuit diagram showing a back gate (BG) voltage control circuit in a drive circuit, FIG. 3 is a circuit diagram showing a memory cell driven by the drive circuit of FIG. 1, FIG. 4 is an explanatory view showing operation of the embodiment, and FIG. 5 is a block diagram showing the entire macro configuration in the embodiment.

A drive circuit of a semiconductor memory device shown in FIG. 1 includes a word line drive circuit 31 and a BG voltage control circuit 32. The word line drive circuit 31, which is the same as that described in the section of prior art, includes a predecoder 21 to which an 8-bit address is input, a row decoder 22, and a word line driver 23. The BG voltage control circuit 32 includes a block selection decoder 24 and a VBEN supply circuit 25 operating as a bias generator.

The block selection decoder 24 in the BG voltage control circuit 32 uses, as an EN signal, e.g., an EN signal (SEL[15:0]) generated using two predecode signals (PD76[3:0], PD54[3:0]) required for dividing a memory cell array section into a 16 blocks in the row direction, in place of the 1/256 hot signal (FD[255:0]) obtained by decoding all bits of an input address signal. FIG. 1 shows a state where one (block BLK[8]) of the 16 blocks is activated.

It goes without saying that a configuration may be adopted in which the other predecode signals may be used to determine selection/nonselection with respect to a smaller block.

Further, a CE signal that forcibly prevents a macro from operating, that is, performs control such that read/write operation is inhibited is incorporated in the block selection decoder 24. This allows control of the back gate as well as selection/nonselection of a row, depending on whether the macro itself is selected or not.

The VBEN supply circuit 25 shown in FIG. 2 is constituted as a power supply generation circuit for BG terminal and includes a reference potential generator 251, a voltage comparator 252, a low-pass filter 253, a voltage controller 254, a charge pump 256, a well short circuit 257, and a feedback potential generation resistor 258 to the voltage comparator 252.

The reference potential generator 251 generates a reference potential under the control of the EN signal (SEL[5.0]). The voltage comparator 252 compares the reference potential and a feedback potential under the control of the EN signal (SEL[15:0]). The comparison result of the voltage comparator 252 is supplied to the voltage controller 254 through the low-pass filter 253, voltage-controlled by the voltage controller 254 under the control of the EN signal (SEL[15:0]), and output from the charge pump 256. The short circuit 257 applies the output voltage of the charge pump 256 to the BG terminal as VBEN or applies VBEN to the BG terminal as VSS under the control of EN signal (SEL[15:0]).

In this example, 15 lines of the EN signal (SEL[15:0])that need not be driven are “L”-signal input lines and, therefore, the internal circuit enters a standby state, and the output (VBEN) of the charge pump 256 is shorted to VSS. The remaining one line is selected as a line to be driven and, since this line is an “H”-signal input line, the internal circuit is activated, whereby VBEN can assume a potential dependent on the reference potential (Vref).

FIG. 3 shows a memory cell circuit having a configuration in which VBEN is connected to respective transistors in a memory cell. One memory cell 10 includes two transfer gates 11 and 12 which are data input/output control transistors for controlling input/output of data on its input and output sides. Gates 11a and 12a of the transfer gates 11 and 12 are connected to a word line WL, and back gates 11b and 12b thereof are connected to an output of the VBEN supply circuit 32.

Further, the BG terminals of two inverters 15 and 16 constituting the memory cell 10 are also connected to the output of the VBEN supply circuit 32. Output terminals of the transfer gates 11 and 12 are connected to bit lines BL and BLX as in the case of the conventional semiconductor memory device.

Although a BG voltage is applied to all the transistors constituting the memory cell, the BG voltage may be applied to only NMOS transistor for simplification of configuration.

Operation of the embodiment will be described below with reference to FIG. 4. FIG. 4 shows a specification in which a VBEN signal is distributed to the memory cell array section. In the memory cell array section, there exist areas where a power supply cell Ps is disposed every predetermined number of columns for “dropping the VBEN signal from the metal layer constituting the word line WL to the Poly layer on which the transistor is formed” “ensuring a wiring channel for power supply”.

The VBEN also uses the areas Ps to be connected to the BG terminal of the NMOS transistor in the memory cell whose operating speed needs to be increased. The VBEN supply line is basically arranged in parallel to the word line WL is connected to respective transistors in the memory cell in the same manner as the word line WL is connected to the respective transistors. However, the BG area of the NMOS transistor is electrically connected to the respective transistors even in the well section.

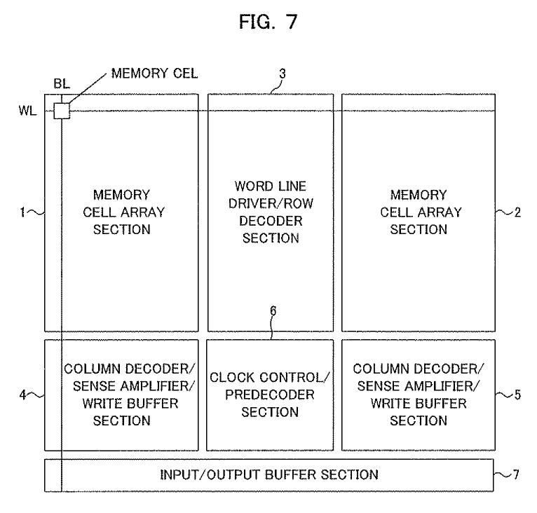

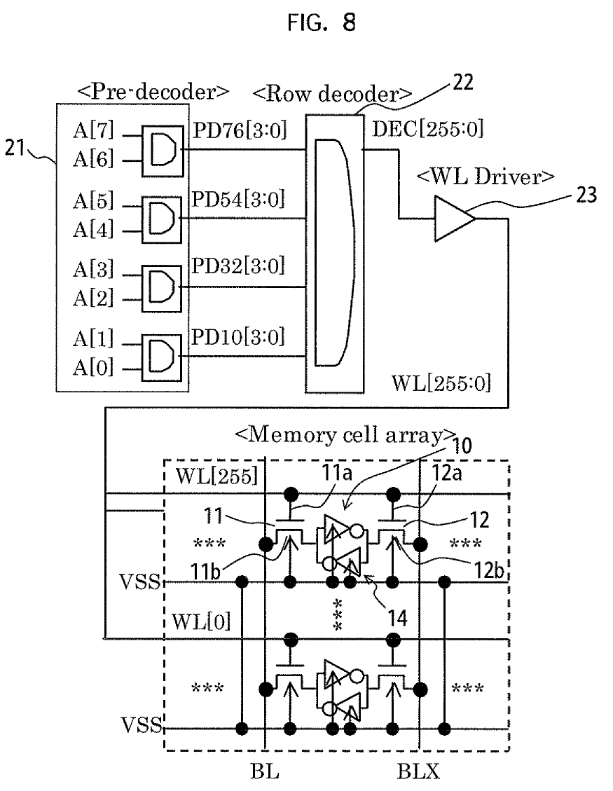

FIG. 5 shows the entire macro configuration in the embodiment. As compared to FIG. 7 showing the entire macro configuration of the conventional semiconductor memory device, the BG voltage control circuit 32 is added to the word line driver section 3.

FIG. 6 shows the effect of the embodiment obtained in the case where the configuration of the embodiment is applied to a 2 kW 1RW Cache RAM. In this example, the word line is divided into 16 blocks. In FIG. 6, respective values of the embodiment in terms of BL Swing, readout time, and standby power requirement are shown in comparison with those of the conventional semiconductor memory device (defined as 1).

In FIG. 6, “BL Swing” denotes a time required for the operation in which a WL (signal selecting row) is activated to select a bit cell and a bit line is discharged to the low level. “Readout time” denotes a sum of the “BL Swing” and operation in which the signal intensity is amplified by the sense amplifier and valid data is output from a data output pin. “Standby power requirement” is a power in the case where the back gate potential of an NMOS in the bit cell in an operating state is set to 0.6V to reduce Vth while the back gate potential of an NMOS in the bit cell in a nonoperating state is set to −0.6V to increase Vth. With respect to the PMOS, the inverse voltages to the above case are applied.

As described above, according to the present invention, it is possible to obtain an advantage of increasing drive capability at operating time while reducing a leak current at standby time without the need to make a significant change to the design of an existing semiconductor memory device.

1. A semiconductor memory device having a memory cell, comprising:
a latch section that includes a transistor having a back gate to which a back gate voltage is supplied;
a memory cell that includes a transfer gate constituting the memory cell, the transfer gate being subjected to switching control by a word line signal and having a back gate to which a back gate voltage is supplied; and
a back gate voltage control circuit that controls the back gate voltage based on an address signal.

2. The semiconductor memory device according to claim 1, wherein the back gate voltage control circuit controls the potential applied to a back gate terminal depending on selection/nonselection of a memory cell so as to reduce the threshold voltage of the transistor in a memory cell selected by the address signal to increase drive capability and to increase the threshold voltage of the transistor in a nonselected memory cell to reduce a leak current.

3. The semiconductor memory device according to claim 1, wherein
the back gate voltage control circuit divides a memory array into a plurality of blocks in a row direction based on an address signal and controls the back gate voltage in units of a block.

4. The semiconductor memory device according to claim 1, wherein
the back gate voltage control circuit uses an output signal of a predecoder of a row decoder for activating a row line based on a received address so as to divide the memory array into a plurality of blocks.

5. The semiconductor memory device according to claim 1, wherein
the back gate voltage control circuit controls the back gate voltage so as to increase the threshold voltage of the transistor at nonoperating time of the entire memory macro to reduce a leak voltage based on a standby mode signal for causing the entire memory macro to enter a nonoperating mode in which READ/WRITE operation is inhibited.

6. The semiconductor memory device according to claim 1, wherein
a voltage supply wiring from the back gate voltage control circuit is formed using a power supply cell.

7. The semiconductor memory device according to claim 1, wherein
the voltage supply wiring from the back gate voltage control circuit is arranged in parallel and adjacent to a row selection signal line (WL).
